(19) United States
(12) Patent Application Publication
(10) Pub. No.: US 2024/0365612 A1
(43) Pub. Date: Oct. 31, 2024

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Shuo LI, Beijing (CN); Ling SHI, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/291,983

(22) PCT Filed: Jun. 29, 2022
(86) PCT No.: PCT/CN2022/102512

§ 371 Date: Jan. 25, 2024

(51) Int. Cl. H10K 59/131; H10K 59/35

(52) U.S. Cl. CPC H10K 59/131; H10K 59/353

(57) ABSTRACT

A display panel and a display device. The display panel comprises: a driving backplane, which comprises a substrate, and a circuit layer, a wiring layer and a first planarization layer, which are sequentially stacked away from the substrate, the circuit layer comprising a plurality of pixel circuits, the wiring layer comprising a data line and a power line distributed in a row direction, the width of the power line being greater than the width of the data line. the power line being provided with a plurality of through holes distributed in a column direction, each through hole being internally provided with an adapter portion, which is on the same layer as and spaced apart from the power line, and one adapter portion being connected to one pixel circuit; light-emitting devices, which are distributed on the side of the first planarization layer away from the substrate and are connected to the pixel circuits, each of which comprises a first electrode, a light-emitting layer and a second electrode, and at least some of the light-emitting devices overlapping with a region of the power line in which no through hole is provided; and an anti-reflection layer, which is arranged on the side of the light-emitting devices away from the substrate and comprises a plurality of light filter portions distributed in an array, one light filter portion overlapping with one light-emitting device, and the light filter portion having the same color as light emitted by the light-emitting device, which light overlaps with the light filter portion.

### TECHNICAL FIELD

The present disclosure relates to the display technical field, and in particular, to a display panel and a display device.

### BACKGROUND

Organic Light-Emitting Diode (OLED) display panel has the advantages of self-illumination, wide color gamut, high contrast, flexibility, high response and flexibility, etc., and has broad application prospects. However, current display panels have phenomena such as color breakup or color shift that affect display effects.

It should be noted that the information disclosed in the background section is only for enhancing the understanding of the background of the present disclosure, and therefore may include information that does not constitute prior art known to those of ordinary skill in the art.

### SUMMARY

The present disclosure provides a display panel and a display device.

According to an aspect of the present disclosure, there is provided a display panel, including:

a driving backplane including a substrate and a circuit layer, a wiring layer and a first planarization layer which are stacked in sequence along a direction away from the substrate; wherein:
the circuit layer includes a plurality of pixel circuits distributed in an array;
the wiring layer includes data lines and power lines distributed along a row direction, and one of the data lines and one of the power lines are connected to a column of the pixel circuits;
the power lines have a width larger than that of the data lines;
the power lines are provided with a plurality of through-holes distributed in a column direction, the through-holes are provided with interconnection portions which are arranged in a same layer as the power lines and are spaced from the power lines, and one of the interconnection portions is connected to one of the pixel circuits;
a plurality of light-emitting devices distributed in an array on a side of the first planarization layer away from the substrate and connected to the pixel circuits, wherein each of the light-emitting devices includes a first electrode, a light-emitting layer and a second electrode which are stacked in sequence along the direction away from the substrate, the light-emitting devices includes at least two kinds of light-emitting devices which emit light of different colors, and at least part of the light-emitting devices overlap with an area of the power lines where no through-hole is provided; and
an anti-reflection layer arranged on a side of the light-emitting devices away from the substrate, and including a plurality of filter portions distributed in an array, wherein one of the filter portions overlaps with one of the light-emitting devices, and a color of one of the filter portions is the same as a color of light emitted by a light-emitting device which overlaps with the one of the filter portions.

In an example implementation of the present disclosure, the data lines and the power lines are alternately distributed along the row direction;
one of the power lines overlaps with a column of the light-emitting devices, and a column of the light-emitting devices is provided between two adjacent data lines; and
among light-emitting devices and power lines which overlap with each other, a boundary of at least part of the light-emitting devices is located within a boundary of power lines which overlap with the at least part of the light-emitting devices.

In an example implementation of the present disclosure, the light-emitting devices are arranged in a plurality of device columns along the row direction, and one of the device columns of the light-emitting devices overlap with one of the power lines.

In an example implementation of the present disclosure, the light-emitting devices include a first light-emitting device of a first color, a second light-emitting device of a second color, and a third light-emitting device of a third color;
a range of the first light-emitting device is larger than that of the second light-emitting device and the third light-emitting device, and a boundary of at least one of the second light-emitting device and the third light-emitting device is located within a boundary of a power line which overlaps with the at least one of the second light-emitting device and the third light-emitting device.

In an example implementation of the present disclosure, the device columns include a first device column and a second device column alternately distributed along the row direction, the first device column includes the first light-emitting device and the second light-emitting device which are alternately distributed along the column direction, and the second device column includes the third light-emitting device.

In an example implementation of the present disclosure, the first electrode includes an electrode body and an electrode connection portion extending outward from the electrode body, and one electrode connection portion is connected to one of the pixel circuits through a contact hole which passes through the first planarization layer;
wherein the display panel further includes:
a pixel definition layer arranged on a side of the first planarization layer away from the substrate and provided with a plurality of openings for defining ranges of the light-emitting devices, one of the openings exposes one electrode body, and a boundary of the one of the openings is located within a boundary of an electrode body exposed by the one of the openings;
a distance between one of the openings and a contact hole connected to an electrode connection portion connected to an electrode body exposed by the one of the openings is an offset distance of a light-emitting device defined by the one of the openings;
wherein the offset distance of the first light-emitting device is 2.9 μm to 3 μm, the offset distance of the second light-emitting device is 6.5 μm to 6.6 μm, and the offset distance of the third light-emitting device is 5.2 μm to 5.3 μm.

In an example implementation of the present disclosure, the data lines are divided into a plurality of data line groups, and one of the data line groups includes two of the data lines;
the power lines are divided into a plurality of power lines groups, and one of the power line groups includes two power lines, and the two power lines are formed as an integrated structure;
the data line groups and the power line groups are alternately distributed along the row direction;
two columns of pixel circuits connected to two power lines in one of the power line groups are arranged symmetrically with respect to a central axis of the two power lines;
a boundary of at least part of the light-emitting devices is located within a boundary of the power line groups, and at most part of the light-emitting devices overlap with the data line groups.

In an example implementation of the present disclosure, the light-emitting devices are arranged in a plurality of device columns along the row direction, and light-emitting devices of a part of the device columns overlap with one of the power line groups, and light-emitting devices of a part of the device columns overlap with the data line groups.

In an example implementation of the present disclosure, the light-emitting devices include a first light-emitting device of a first color, a second light-emitting device of a second color, and a third light-emitting device of a third color;
a range of the first light-emitting device is larger than that of the second light-emitting device and the third light-emitting device, a boundary of the first light-emitting device is located within a boundary of a power line group which overlaps with the first light-emitting device, and at most one of the second light-emitting device and the third light-emitting device overlaps with the data line group.

In an example implementation of the present disclosure, the device columns include a first device column and a second device column alternately distributed along the row direction;
the first device column includes the first light-emitting device and the second light-emitting device which are alternately distributed along the column direction, and the second device column includes the third light-emitting device; and
a boundary of light-emitting devices of the first device column are located within a boundary of a power line group which overlaps with the light-emitting devices of the first device column, and light-emitting devices of the second device column overlap with a data line group.

In an example implementation of the present disclosure, the first electrode includes an electrode body and an electrode connection portion extending outward from the electrode body, and one electrode connection portions is connected to one of the pixel circuits through a contact hole which passes through the first planarization layer;
wherein the display panel further includes:
a pixel definition layer arranged on a side of the first planarization layer away from the substrate and provided with a plurality of openings for defining ranges of the light-emitting devices, one of the openings exposes one electrode body, and a boundary of the one of the openings is located within a boundary of an electrode body exposed by the one of the openings;
a distance between one of the openings and a contact hole connected to an electrode connection portion connected to an electrode body exposed by the one of the openings is an offset distance of a light-emitting device defined by the one of the openings;
wherein the offset distance of the first light-emitting device is 9 μm to 11 um, the offset distance of the second light-emitting device is 15 μm to 17 μm, and the offset distance of the third light-emitting device is 6 μm to 8 μm.

In an example implementation of the present disclosure, each of the pixel circuits includes a plurality of transistors;
the circuit layer includes a semiconductor layer, a first gate insulating layer, a first gate layer, a second gate insulating layer, a second gate layer, a dielectric layer, a source-drain layer, a passivation layer, and a second planarization layer which are distributed along the direction away from the substrate;
the wiring layer is arranged on a side of the second planarization layer away from the substrate; and
channels of the transistors are located in the semiconductor layer.

In an example implementation of the present disclosure, in a pixel circuit and a data line and a power line connected to the pixel circuit, the pixel circuit includes a first reset transistor, a compensation transistor, a driving transistor, a writing transistor, a first light-emitting control transistor, a second light-emitting control transistor, a second reset transistor and a storage capacitor;
a first electrode of the first reset transistor is used to receive a first reset signal, and a second electrode of the first reset transistor is connected to a gate of the driving transistor and a first electrode plate of the storage capacitor;
a first electrode of the compensation transistor is connected to a second electrode of the driving transistor, and a second electrode of the compensation transistor is connected to the gate of the driving transistor, and the compensation transistor has two channels connected in series;
a first electrode of the writing transistor is connected to one of the data lines, and a second electrode of the writing transistor is connected to a first electrode of the driving transistor;
a first electrode of the first light-emitting control transistor is connected to a second electrode plate of the storage capacitor and the power line, and a second electrode of the first light-emitting control transistor is connected to the first electrode of the driving transistor;
a first electrode of the second light-emitting control transistor is connected to the second electrode of the driving transistor, and a second electrode of the second light-emitting control transistor is connected to one first electrode through an interconnection portion;
a first electrode of the second reset transistor is used to receive a second reset signal, and a second electrode of the second reset transistor is connected to the second electrode of the second light-emitting control transistor;
the first gate layer includes gates of the transistors and the first electrode plate of the storage capacitor, the second gate layer includes the second electrode plate of the storage capacitor, a shielding block and a screening block, the source-drain layer includes a connection portion connecting the second electrode of the compensation transistor and the gate of the driving transistor, and the connection portion and the gate of the driving transistor are located on the same side of the data line;
at least a partial area of the shielding block overlaps with a semiconductor layer between the two channels of the compensation transistor, the screening block is at least partially located between the data line and the connection portion, and the screening block is connected to the power line.

In an example implementation of the present disclosure, the display panel includes a display area, and the display area includes an auxiliary display area and a main display area outside the auxiliary display area, and the light-emitting devices are distributed in the main display area and the auxiliary display area;
wherein a pixel circuit connected to at least part of the light-emitting devices in the auxiliary display area is located in the main display area and connected to the light-emitting devices through a conductive line;
wherein the circuit layer further includes a conductive layer and an insulating layer, the conductive layer is arranged on a side of the passivation layer away from the substrate, the insulating layer covers the conductive layer, the second planarization layer covers the insulating layer, and the conductive layer includes the conductive line;

In an example implementation of the present disclosure, the conductive layer further includes a plurality of overlapping portions located in the display area, and one of the pixel circuits is connected to a power line through one of the overlapping portions.

According to an aspect of the present disclosure, there is provided a display device, including the display panel described in any one of the above implementations.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of the specification, illustrate embodiments consistent with the present disclosure and together with the specification serve to explain the principles of the present disclosure. Apparently, the drawings in the following description are only some embodiments of the present disclosure, and those skilled in the art may obtain other drawings according to these drawings without creative efforts.

FIG. 1 is a schematic diagram of a display area and a peripheral area of a display panel according to an implementation of the present disclosure.

FIG. 2 is a partial cross-sectional view of a display panel according to an implementation of the present disclosure.

FIG. 3 is a schematic diagram of a light-emitting device and a wiring layer of a display panel according to a first implementation of the present disclosure.

FIG. 4 is a schematic diagram of a light-emitting device and a wiring layer of a display panel according to a second implementation of the present disclosure.

FIG. 5 is a schematic diagram showing principle of a pixel circuit in a display panel according to an implementation of the present disclosure.

FIG. 6 to FIG. 12 are partial top views of film layers of the display panel according to the first implementation of the present disclosure.

FIG. 13 is a partial top view of a semiconductor layer and a first gate layer of the display panel according to the first implementation of the present disclosure.

FIG. 14 is a partial top view of a semiconductor layer to a second gate layer of the display panel according to the first implementation of the present disclosure.

FIG. 15 is a partial top view of a semiconductor layer to a conductive layer of the display panel according to the first implementation of the present disclosure.

FIG. 16 is a partial top view of a semiconductor layer to a wiring layer of the display panel according to the first implementation of the present disclosure.

FIG. 17 is a partial top view of the display panel according to the first implementation of the present disclosure.

FIG. 18 to FIG. 24 are partial top views of film layers of the display panel according to the second implementation of the present disclosure.

FIG. 25 is a partial top view of a semiconductor layer and a first gate layer of the display panel according to the second implementation of the present disclosure.

FIG. 26 is a partial top view of a semiconductor layer to a second gate layer of the display panel according to the second implementation of the present disclosure.

FIG. 27 is a partial top view of a semiconductor layer to a conductive layer of the display panel according to the second implementation of the present disclosure.

FIG. 28 is a partial top view of a semiconductor layer to a wiring layer of the display panel according to the second implementation of the present disclosure.

FIG. 29 is a partial top view of the display panel according to the second implementation of the present disclosure.

### DETAILED DESCRIPTION

Example implementations will now be described more fully with reference to the accompanying drawings. Example implementations may, however, be embodied in many forms and should not be construed as being limited to the implementations set forth herein; rather, these implementations are provided so that the present disclosure will be thorough and complete, and will fully convey the concept of example implementations to those skilled in the art. The same reference numerals in the drawings denote the same or similar structures, and thus their repeated descriptions will be omitted. Furthermore, the drawings are merely schematic illustrations of the present disclosure and are not necessarily drawn to scale.

The terms “one”, “a/an”, “the”, “said” and “at least one” are used to indicate the presence of one or more elements/components/etc.; the terms “comprising/comprises/comprise” and “having/has/have” are used to indicate an open-ended inclusive, and means that there may be additional elements/components/etc. in addition to the listed elements/components/etc. The words “first”, “second” and “third” are used as markers only, but are not used to limit the number of objects.

A row direction X and a column direction Y herein are merely two directions perpendicular to each other. In the drawings of the present disclosure, the row direction X may be horizontal, and the column direction Y may be vertical, but the present disclosure is not limited thereto. If a display panel rotates, the actual orientation of the row direction X and the column direction Y may change.

In the present disclosure, a feature A overlapping with a feature B means that an orthographic projection of the feature A on an substrate and an orthographic projection of the feature B on the substrate are at least partially coincident.

Transistors in a pixel circuit of the present disclosure may be N-type transistors, P-type transistors, or both. A transistor may have a gate, a first electrode and a second electrode. The gate may be used to control on and off of the transistor. The first electrode and the second electrode may be used for input and output signals, and the first electrode may be a source of the transistor, and the second electrode may be a drain of the transistor. But, when the operating state of the transistor changes, such as when the direction of current flow changes, the source and drain of the transistor may be interchanged.

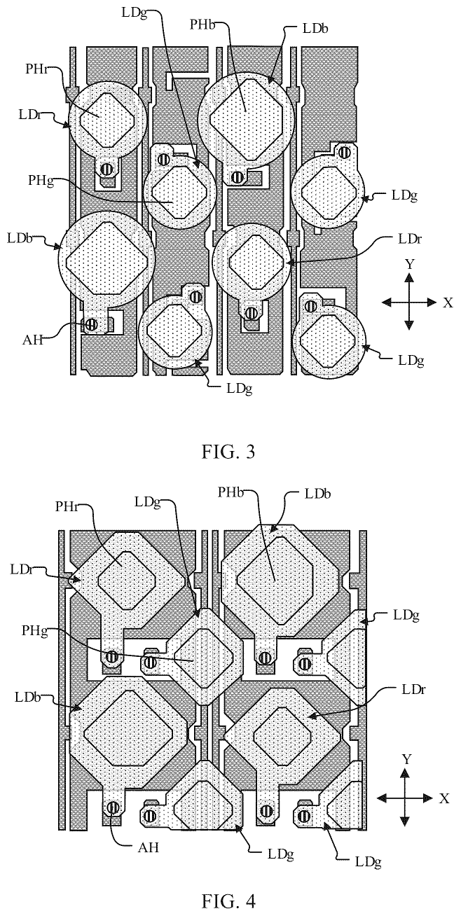

As shown in FIGS. 2 to 4, an implementation of the present disclosure provides a display panel, which may include a driving backplane BP, light-emitting devices LD, and an anti-reflection layer COE.

The driving backplane BP may include a substrate SU and a circuit layer CL, a wiring layer SD2 and a first planarization layer PLN2 which are stacked in sequence along a direction away from the substrate SU. The circuit layer CL includes a plurality of pixel circuits PC distributed in an array. The wiring Layer SD2 includes data lines DAL and power lines VDL distributed along the row direction X. One of the data lines DAL and one of the power lines VDL are connected to a column of pixel circuits PC. The width of a power line VDL is larger than that of a data line DAL. A power line VDL is provided with a plurality of through-holes VDH distributed along the column direction. The through-holes VDH are provided with interconnection portions VDL1 which are arranged in a same layer as the power lines VDL and are spaced from the power lines VDL, and one of the interconnection portions VDL1 is connected to one of the pixel circuits PC.

There are a plurality of light-emitting devices, and the light-emitting devices are distributed in an array on a side of the first planarization layer PLN2 away from the substrate SU and are connected to the pixel circuits PC. A light-emitting device LD includes a first electrode ANO, a light-emitting layer EL and a second electrode CAT which are stacked in sequence along the direction away from the substrate SU. The light-emitting devices LD include at least two kinds of light-emitting devices LD which emit light of different colors. At least part of the light-emitting device LD overlap with the power lines VDL.

The anti-reflection layer COE may be arranged on a side of the light-emitting devices LD away from the substrate SU, and includes a plurality of filter portions CF distributed in an array. One of the filter portions CF overlaps with one of the light-emitting devices LD. The color of a filter portion CF is the same as the color of light emitted by a light-emitting device LD which overlaps with the filter portion CF.

In the display panel of an embodiment of the present disclosure, the filter portions CF of the anti-reflection layer COE can only transmit monochromatic light, so that the filter portions CF can be used to reduce the ambient light entering the display panel. Even if part of the ambient light is reflected by the light-emitting devices LD and the pixel circuits PC, the ambient light reflected in part is blocked by the filter portions CF and cannot be emitted, thereby reducing the reflection of the ambient light by the display panel and playing the role of a circular polarizer, and thus eliminating the need for a large thick circular polarizer. Accordingly, the thickness of the display panel can be reduced. At the same time, the first electrode ANO is made of reflective material. Since the width of the power line VDL is larger than that of the data line DAL, and an area where no through-hole VDH is provided overlaps with a light-emitting device LD, it is beneficial to make the first electrode ANO flatter and avoid that unevenness of the first electrode ANO interferes with the propagation of light, thereby alleviating the phenomenon of color breakup or color shift when the light exits from the anti-reflection layer COE due to the interference of the optical path.

The overall structure of the display panel of the present disclosure will be described in detail below.

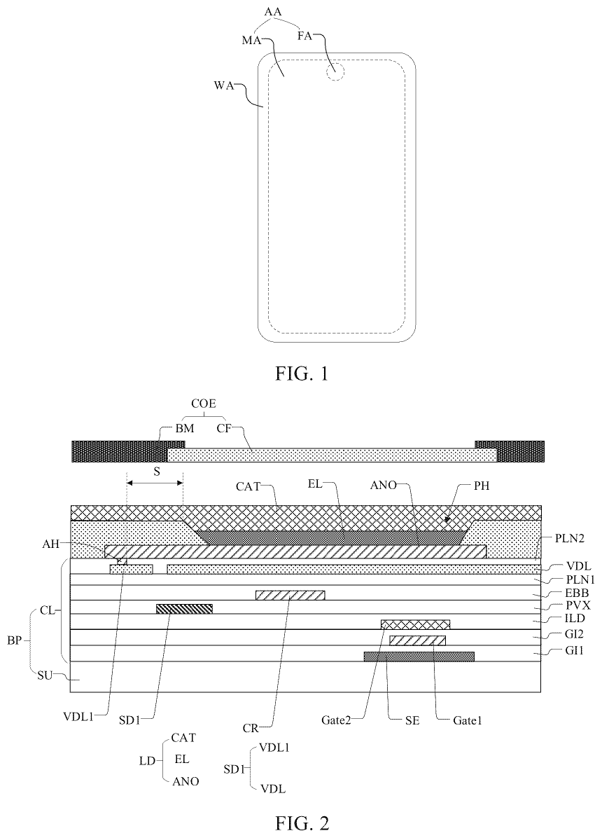

As shown in FIG. 1, the display panel may have a display area AA and a peripheral area WA outside the display area AA. The peripheral area WA may be a continuous or discontinuous annular area surrounding the display area AA, or may be a semi-closed area, and there is no special limitation on the shape of the peripheral area WA in embodiments of the present disclosure. The light-emitting devices LD may be distributed in the display area AA, and images may be displayed by making the light-emitting devices LD emit light, while the peripheral area WA does not emit light.

As shown in FIG. 2, the driving backplane BP may include a substrate SU, and a circuit layer CL, a wiring layer SD2 and a first planarization layer PLN2 which are stacked on a side of the substrate SU.

The substrate SU may be the base of the driving backplane BP, which may carry the circuit layer CL. The substrate SU may be a rigid or flexible structure, and it may be a single-layer or multi-layer structure, which is not specifically limited here.

The circuit layer CL may include driving circuits for driving the light-emitting devices LD to emit light independently to display images. The driving circuits may include pixel circuits PC and peripheral circuit(s). The pixel circuits PC may be located in the display area AA and connected to the light-emitting devices LD. Of course, a part of areas of a part of the pixel circuits PC may be located in the peripheral area WA. The peripheral circuit(s) is (are) located in the peripheral area WA, and the peripheral circuit(s) is (are) connected to the pixel circuits PC. On the one hand, the peripheral circuit(s) may be connected to the light-emitting devices LD through the pixel circuits PC to apply a first power signal VDD to the first electrodes ANO of the light-emitting devices LD. On the other hand, the peripheral circuit(s) may also be connected to the second electrodes CAT of the light-emitting devices LD, and apply a second power signal VSS to the second electrodes CAT. The current through the light-emitting devices LD may be controlled by controlling the pixel circuits PC, thereby controlling the brightness of the light-emitting devices LD. The peripheral circuit(s) may include a gate driving circuit, and a light-emitting control circuit, etc. Of course, the peripheral circuit(s) may further include other circuits, and the specific structure of the peripheral circuit(s) is not specifically limited here.

Each pixel circuit PC may include a plurality of transistors and a storage capacitor. Channels of the transistors may be arranged in the same layer, and all of them are made of semiconductor materials such as polysilicon. The pixel circuit PC may include a plurality of transistors, and may further include a capacitor. The pixel circuit PC may be 3T1C, 7T1C or other pixel circuits PC, where nTmC means that a pixel circuit PC includes n transistors (indicated by the letter “T”) and m capacitors (indicated by the letter “C”). The number of pixel circuits PC may be multiple, and the pixel circuits PC may be distributed in an array of multiple rows and columns. One pixel circuit PC may be connected to one light-emitting device LD. Of course, there may also be a situation where one pixel circuit PC is connected to multiple light-emitting devices LD. In the following description, a one-to-one connection between the pixel circuits PC and the light-emitting devices LD is taken as an example for illustration.

As shown in FIG. 2, the wiring layer SD2 is arranged on a side of the circuit layer CL away from the substrate SU, and at least includes a data line DAL and a power line VDL connected to a pixel circuits PC. The wiring layer SD2 and the circuit layer CL may form a driving circuit.

As shown in FIG. 3 and FIG. 4, there are multiple data lines DAL and power lines VDL, and they all extend along the column direction Y and are distributed along the row direction X. One data line DAL may be connected to at least one column of pixel circuits PC, and one power line VDL may be connected to at least one column of pixel circuits PC. The data lines DAL may input a data signal DA to the pixel circuits PC, and the power lines VDL may input a first power signal VDD to the pixel circuits PC.

As shown in FIG. 2, the first planarization layer PLN2 may cover the wiring layer SD2, and the material of the first planarization layer PLN2 may be an organic material such as transparent resin, and a surface of the first planarization layer PLN2 away from the driving backplane BP is a plane, in order to arrange the light-emitting devices LD thereon.

As shown in FIG. 2, the light-emitting devices LD may be distributed in an array on a surface of the first planarization layer PLN2 away from the wiring layer SD2. The light-emitting devices LD may be organic light emitting diodes. A light-emitting device may include a first electrode, a light-emitting layer EL and a second electrode CAT which are stacked in a direction away from the substrate SU.

A first electrode ANO is connected to a pixel circuit PC, and the first electrode ANO is used as an anode, which may be a single-layer or multi-layer structure, and its material may include one or more of conductive metal, metal oxide and alloy. The first electrode ANO may be a light-shielding structure. For example, the first electrode ANO may include three metal layers, the material of the middle metal layer may be silver, or aluminum, etc., and the material of the other two metal layers may be titanium or other metals, and no special limitation is made here.

As shown in FIG. 2, the light-emitting layer EL is at least partially disposed in an opening PH, and may include a hole injection layer, a hole transport layer, a light-emitting material layer, an electron transport layer, and an electron injection layer which are sequentially stacked in a direction away from the substrate SU. Holes and electrons may be recombined into excitons in the light-emitting material layer, and the excitons radiate photons to generate visible light. The specific light-emitting principle will not be described in detail here. The light-emitting layers EL may be distributed in an array, and each light-emitting device LD has a light-emitting layer EL that emits light independently, so that each light-emitting device LD may emit light independently, and the colors of light emitted by different light-emitting devices LD may be different. For example, there are multiple light-emitting layers EL, and the light-emitting layers EL are distributed in an array in openings PH, and are stacked with the first electrodes ANO exposed by the openings PH. Alternatively, the light-emitting layers EL may share at least part of the film layers except the light-emitting material layer, but the light-emitting material layer is independently provided, so that light-emitting devices LD which emit light of different colors may also be obtained.

As shown in FIG. 2, the second electrode CAT may cover the light-emitting layer EL, which may be used as the cathode of the light-emitting device LD. The second electrode CAT may be a single-layer or multi-layer structure, and its material may include one or more of conductive metal, metal oxide and alloy. The light-emitting devices LD may share the same second electrode CAT. Specifically, the second electrode CAT is a continuous conductive layer CR covering the light emitting layers EL and the pixel definition layers PDL of the light-emitting devices LD, that is, the orthographic projection of the second electrode CAT on the pixel definition layer(s) PDL covers the respective openings PH.

As shown in FIG. 2, in order to limit the range of each light-emitting device LD, a pixel definition layer PDL may also be provided on a surface of the first planarization layer PLN2 away from the substrate SU. The pixel definition layer PDL may be used to separate the light-emitting devices LD, thereby preventing cross-color of adjacent light-emitting devices LD. Specifically, the pixel definition layer PDL may be provided with a plurality of openings PH, and the openings PH expose the first electrodes ANO in a one-to-one correspondence, and the boundary of an opening PH is located within the boundary of a first electrode ANO exposed by the opening PH. The range defined by each opening PH is the range of a light-emitting device LD.

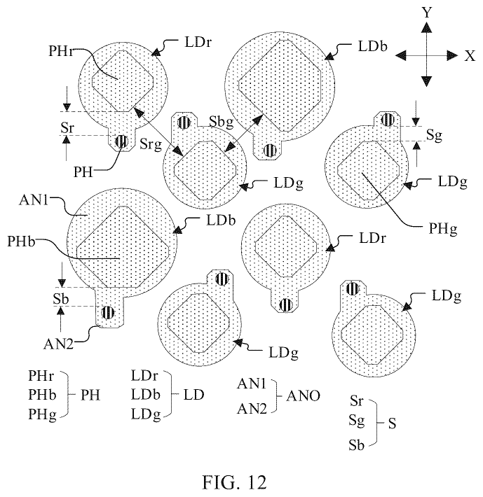

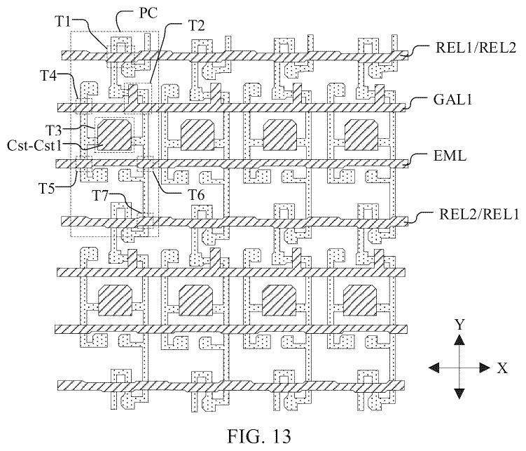

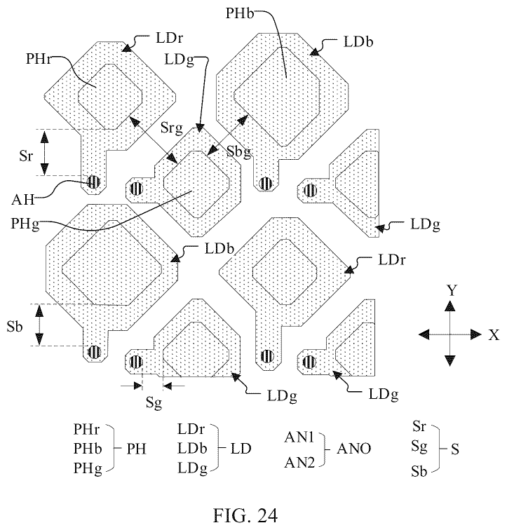

Further, as shown in FIG. 2, FIG. 12 and FIG. 24, the first electrode ANO may include an electrode body AN1 and an electrode connection portion AN2 extending outward from the electrode body AN1. An opening PH exposes an electrode body AN1, and the boundary of the opening PH is located within the boundary of an electrode body AN1 exposed by the opening PH. The electrode connection portion AN2 extends beyond the boundary of the opening PH, and may be connected to a pixel circuit PC through a contact hole AH penetrating the first planarization layer PLN2, so that the contact hole AH is not required to be set in the range of the light-emitting device LD, so as to avoid affecting light-emitting area. Meanwhile, a distance between an opening PH and a contact hole AH connected to the electrode connection portion AN2 connected to the electrode body AN1 exposed by the opening PH may be defined as an offset distance of the light-emitting device LD defined by the opening PH. The inventors of the present disclosure have found that the contact hole AH and the opening PH may affect the flatness of the first planarization layer PLN2, and the smaller the offset distance, the more uneven the first planarization layer PLN2 around the electrode body AN1, which will cause that the first electrode ANO is not flat, which may also cause problems such as color breakup and color shift.

The light-emitting devices LD may include a first light-emitting device LDb of a first color, a second light-emitting device LDr of a second color, and a third light-emitting device LDg of a third color. The first color may be blue, the second color may be red, and the third color may be green. In order to ensure the consistency of the lifetime of the light-emitting devices LD, the range of the first light-emitting device LDb (the range of the opening PHb of the first light-emitting device LDb) may be made larger than the range of the second light-emitting device LDr (the range of the opening PHb of the second light-emitting device LDr) and the third light-emitting device LDg (the range of the opening PHg of the third light-emitting device LDg). By increasing the size, the life of the blue colored light-emitting device LD with a shorter life may be improved. In addition, the range of the second light-emitting device LDr may be greater than the range of the third light-emitting device LDg.

The light-emitting devices LD may be arranged into multiple device columns along the row direction X, and one device column may include multiple light-emitting devices LD distributed along the column direction Y, for example:

Each device column may include a first device column and a second device column alternately distributed along the row direction X, the first device column may include a first light-emitting device LDb and a second light-emitting device LDr alternately distributed along the column direction Y, and the second device column includes a third light-emitting device LDg. That is, the third light-emitting device LDg is not in the same column as the first light-emitting device LDb and the second light-emitting device LDr.

As shown in FIG. 12 and FIG. 24, in some implementations of the present disclosure, the light-emitting devices LD may be divided into a plurality of light emitting units, and each light emitting unit may include one first light-emitting device LDb, one second light-emitting device LDr and two third light-emitting devices LDg. The first light-emitting device LDb and the second light-emitting device LDr may be distributed along the column direction Y, and the two third light-emitting devices LDg may be distributed on both sides of the first light-emitting device LDb and the second light-emitting device along the row direction X, so that the light-emitting devices are distributed as a quadrilateral. The quadrilateral may be a rhombus. Adjacent light emitting units may share part of the light-emitting device(s) LD, or alternatively, may not share a light-emitting device LD. In addition, in other implementations of the present disclosure, the light-emitting devices LD may be arranged in other ways, and there is no special limitation on the way of arrangement here, and the above description only uses the rhombus arrangement as an example for illustration.

As shown in FIG. 2, the anti-reflection layer COE may be arranged on a side of the light-emitting devices LD away from the driving backplane BP, and has a plurality of filter portions CF. The filter portions CF may be used to transmit monochromatic light, and the monochromatic light may be red light, blue light, green light, etc. The filter portions CF may overlap with the light-emitting devices LD in one-to-one correspondence, and the color of a light-emitting device LD and a color of a filter portion CF which overlaps with the light-emitting device LD are the same, that is, the color of the light emitted by the light-emitting device LD and the color of the filter portion CF which overlaps with the light-emitting device LD are the same. Meanwhile, the anti-reflection layer COE may further include light shielding portions BM separating the filter portions CF, and the light shielding portions BM may be made of black resin material, and of course, other material may be used, as long as it can shield light. Further, in order to improve light extraction efficiency and reduce shielding by the light shielding portion BM, the orthographic projection of a light-emitting device LD on the substrate SU may be located within the orthographic projection of a filter portion OF which overlaps with the light-emitting device LD on the substrate SU.

In addition, the display panel may further include an encapsulation layer, which may cover the light-emitting devices LD, and is used to protect the light-emitting devices LD, and prevent external water and oxygen from corroding the light-emitting devices LD. The anti-reflection layer COE may be arranged on a side of the encapsulation layer away from the substrate SU. For example, the encapsulation layer may realize encapsulation by thin film encapsulation, which may include a first inorganic layer, an organic layer and a second inorganic layer. The first inorganic layer covers the light-emitting devices LD, the organic layer may be arranged on a surface of the first inorganic layer away from the driving backplane BP, and the boundary of the organic layer is defined in the inner side of the boundary of the first inorganic layer. The boundary of the orthographic projection of the organic layer on the driving backplane BP may be located in the peripheral area WA, ensuring that the organic layer can cover the light-emitting devices LD. The second inorganic layer may cover the organic layer and the first inorganic layer not covered by the organic layer, the second inorganic layer may block intrusion of water and oxygen, and the flexible organic layer may realize planarization.

In some implementations of the present disclosure, the display panel may further include a touch layer, which may be arranged between the anti-reflection layer COE and the encapsulation layer. The touch layer may adopt a self-capacitance or mutual-capacitance touch structure. There is no special limitation on specific structure of the touch layer in embodiments of the present disclosure, as long as it can realize the touch function. Alternatively, the touch layer may be arranged on a side of the anti-reflection layer COE away from the driving backplane BP, and its specific position and process are not limited here.

In addition, in some implementations of the present disclosure, the display panel may further include a transparent cover plate, which may be adhered to the anti-reflection layer COE, and may be planarized. The transparent cover plate is used to protect lower film layer(s), and its material may be transparent material such as glass or acrylic, which is not specifically limited here.

In some implementations of the present disclosure, as shown in FIG. 1, the display panel may be a display panel capable of taking pictures under the screen, and its displayable area AA may include an auxiliary display area FA and a main display area MA outside the auxiliary display area FA. Light-emitting devices LD may be distributed in the main display area MA and the auxiliary display area FA. Pixel circuits PC connected to at least part of the light-emitting devices LD in the auxiliary display area FA may be located in the main display area MA, and connected to the light-emitting devices LD through conductive lines, so that the number of pixel circuits PC in the auxiliary display area FA may be reduced, thus increasing the light transmittance of the auxiliary display area FA, so that under-screen photography may be realized through the auxiliary display area FA. Of course, in order to accommodate more pixel circuits PC in the main display area MA, the size of some pixel circuits PC may be compressed, for example, the width of some pixel circuits PC may be reduced along the row direction X. The conductive lines may be made of transparent conductive material such as indium tin oxide to increase the light transmittance of the auxiliary display area FA, and may extend from the auxiliary display area FA to the main display area MA, and the lengths of different conductive lines may be different. The conductive lines may be located in the circuit layer CL, or between the driving backplane BP and the light-emitting devices LD. The present disclosure takes the conductive lines being located in the circuit layer CL as an example for illustration.

The following is an exemplary description of the structure of the pixel circuits PC of the present disclosure.

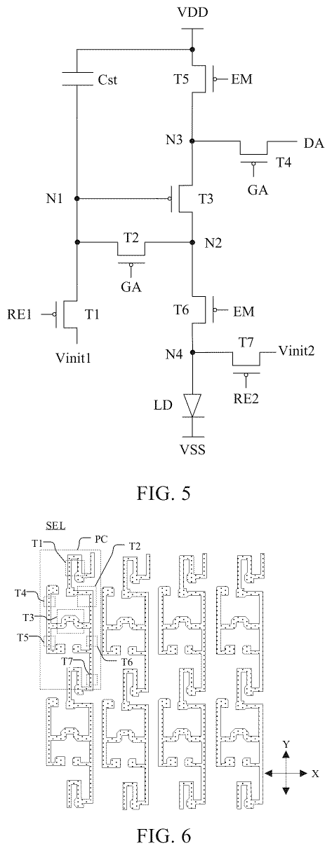

In some implementations of the present disclosure, as shown in FIG. 5, a pixel circuit PC may have a 7T1C structure, that is, the pixel circuit may have 7 transistors and 1 capacitor, that is, a first reset transistor T1, a compensation transistor T2, a driving transistor T3, a writing transistor T4, a first light-emitting control transistor T5, a second light-emitting control transistor T6, a second reset transistor T7 and a storage capacitor Cst.

As shown in FIG. 5, a first electrode of the first reset transistor T1 is connected to a first reset signal line VIL1 for receiving a first reset signal Vinit1, and a second electrode of the first reset transistor T1 is connected to a gate of the driving transistor T3 and a first electrode plate of the storage capacitor Cst.

A first electrode of the compensation transistor T2 is connected to a second electrode of the driving transistor T3, and a second electrode of the compensation transistor T2 is connected to the gate of the driving transistor T3.

A first electrode of the writing transistor T4 is connected to a data line DAL for receiving a data signal DA, and a second electrode of the writing transistor T4 is connected to a first electrode of the driving transistor T3.

A first electrode of the first light-emitting control transistor T5 is connected to a second electrode plate of the storage capacitor Cst and a power line VDL for receiving a first power signal VDD, and a second electrode of the first light-emitting control transistor T5 is connected to the first electrode of the driving transistor T3.

A first electrode of the second light-emitting control transistor T6 is connected to the second electrode of the driving transistor T3, and a second electrode of the second light-emitting control transistor T6 is connected to a first electrode ANO of a light-emitting device LD.

A first electrode of the second reset transistor T7 is connected to a second reset signal line VIL2 for receiving a second reset signal Vinit2, and a second electrode of the second reset transistor T7 is connected to the second electrode of the second light-emitting control transistor T6. A second electrode CAT of the light-emitting device LD may receive a second power signal VSS.

Meanwhile, in order to control turning-on and turning-off of the transistors, the gate of the first reset transistor T1 is connected to a first reset control line RE L1 for inputting a first reset control signal RE1, the gate of the second reset transistor T7 is connected to a second reset control line REL2 for inputting a second reset control signal RE2. The gates of the compensation transistor T2 and the writing transistor T4 are connected to a scan line GL for inputting a scan signal GA. The gates of the first light-emitting control transistor T5 and the second light-emitting control transistor T6 are connected to a light-emitting control line EML for inputting a light-emitting control signal EM. The pixel circuit PC may be used to drive the connected light-emitting device LD to emit light in response to the signals provided by the connected signal terminals.

In addition, transistors may be divided into N-type and P-type transistors according to their characteristics. In the embodiments of the present disclosure, the transistors are P-type transistors as an example for description. Based on the description and teaching of the implementations in the present disclosure, those skilled in the art may easily think of using N-type transistors for at least some of the transistors in the structure of the pixel circuit PC in the embodiments of the present disclosure without making creative efforts, that is, an implementation of using N-type transistors or a combination of N-type transistors and P-type transistors are also possible. Therefore, these implementations also fall within the protection scope of the embodiments of the present disclosure.

Taking transistors of the pixel circuit PC being P-type low-temperature polysilicon transistors as an example, working principle(s) of the pixel circuit PC will be described below.

In a reset phase: the first reset control signal RE1 is a low-level signal, the first reset transistor T1 is turned on, the reset signal Vinit1 is written into the gate of the driving transistor T3 and the first electrode plate of the storage capacitor Cst to realize initialization of a node N1, so as to eliminate influence of data of a previous frame image.

In a writing stage: the scan signal GA is a low-level signal, the writing transistor T4 and the compensation transistor T2 may be turned on, and the data signal DA is written to the gate of the driving transistor T3 and the first electrode plate Cst1 of the storage capacitor Cst, that is, the data signal DA is written into the node N1 through a node N3 and a node N2 until the potential reaches Vdata+Vth, where Vdata is the voltage of the data signal DA, and Vth is the threshold voltage of the driving transistor T3. The scan signals GA for the writing transistor T4 and the compensation transistor T2 may be the same signal. At the same time, the second reset control signal RE2 is a low-level signal, so that the second reset transistor T7 is turned on, and the second reset signal Vinit2 is written into the first electrode ANO of the light-emitting device LD and the second electrode of the second light-emitting control transistor T6 to reset a node N4 to realize initialization, and further eliminates the influence of the data of the previous frame image.

In a light-emitting phase: the light-emitting control signal EM is a low-level signal, the first light-emitting control transistor TS and the second light-emitting control transistor T6 are turned on, and the driving transistor T3 is turned on under the action of the voltage Vdata+Vth stored in the storage capacitor Cst and the first power signal VDD, and at this time, the light-emitting device LD emits light.

The following takes the above-mentioned 7T1C pixel circuit as an example to describe the driving backplane BP in detail.

In some implementations, as shown in FIG. 2, the transistors and capacitor of the pixel circuit PC are both located in the circuit layer CL. Taking the transistors of the pixel circuit PC being top-gate low-temperature polysilicon transistors as an example, the circuit layer CL may include a semiconductor layer SEL, a first gate insulating layer GI1, a first gate layer GAT1, a second gate insulating layer GI2, a second gate layer GAT2, a dielectric layer ILD, a source-drain layer SD1, a passivation layer PVX and a second planarization layer PLN1 which are distributed in a direction away from the substrate SU.

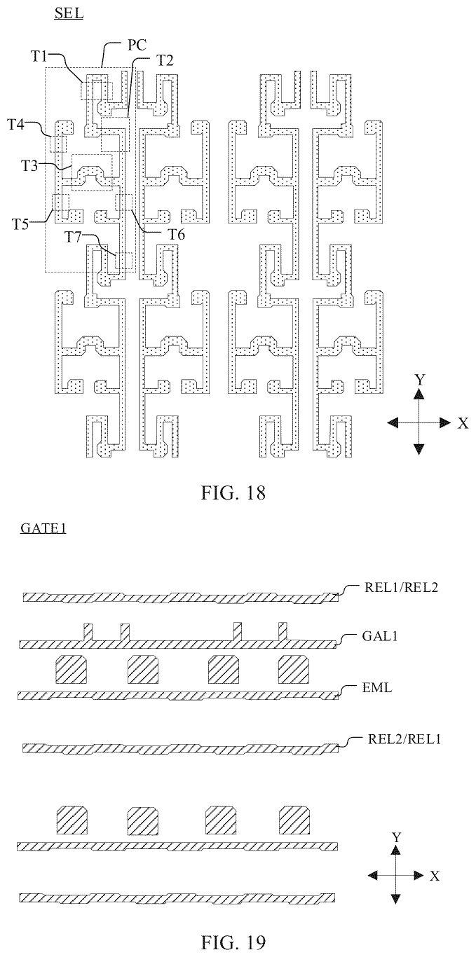

As shown in FIG. 6 and FIG. 18, the semiconductor layer SEL may include channels of transistors (T1 to T7) and doped regions connecting at least part of the channels, and a part of the transistors may be connected through the doped regions.

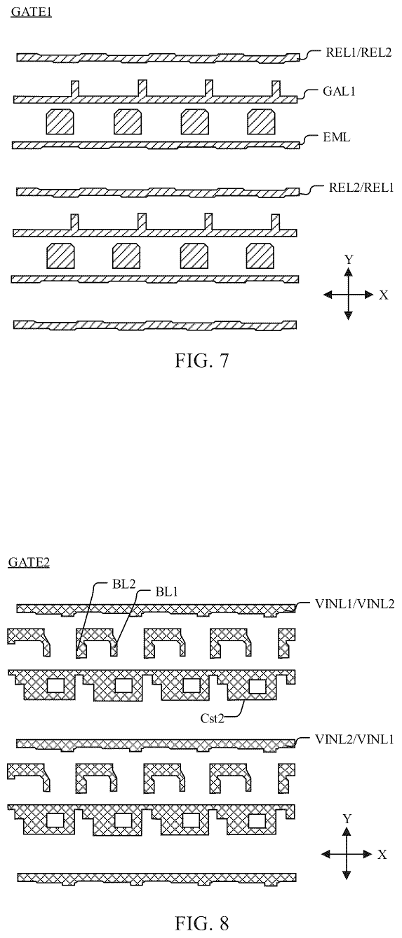

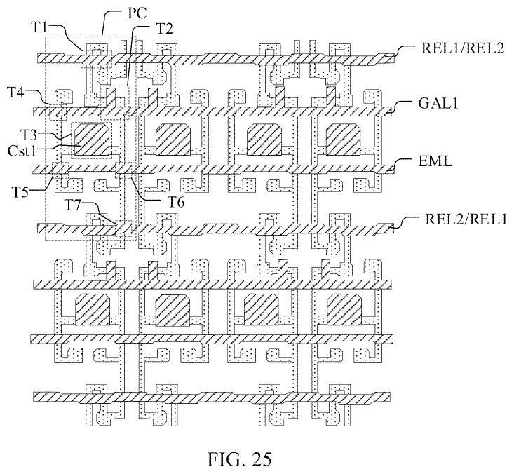

As shown in FIG. 7, FIG. 13, FIG. 19 and FIG. 25, the first gate layer GAT1 may include the first electrode plate Cst1 of the storage capacitor Cst, the scan line GL, the first reset control line REL1, the second reset control line REL2 and the light-emitting control line EML. An area where the scan line GL overlaps with the semiconductor layer SEL is the gates of the writing transistor T4 and the compensation transistor T2. An area where the first reset control line REL1 overlaps with the semiconductor layer SEL is the gate of the first reset transistor T1. An area where the second reset control line REL2 overlaps with the semiconductor layer SEL is the gate of the second reset transistor T7. An area where the light-emitting control line EML overlaps with the semiconductor layer SEL is the gates of the first light-emitting control transistor T5 and the second light-emitting control transistor T6. An area where the first electrode plate Cst1 overlaps with the semiconductor layer SEL is the gate of the driving transistor T3, that is, the first electrode plate Cst1 is reused as the gate of the driving transistor T3. Two areas connected with each other where the scan line GL overlaps with the semiconductor layer SEL form two channels connected in series, and the two channels are channels of the compensation transistor T2.

In addition, the second reset control line REL2 connected to an n-th row of pixel circuits PC may be reused as a first reset control line REL1 connected to a (n+1)-th row of pixel circuits PC, so that when the n-th row of pixel circuits PC are in the reset phase, the (n+1)-th row of pixel circuits PC may reset the light-emitting devices LD, thereby improving the working efficiency.

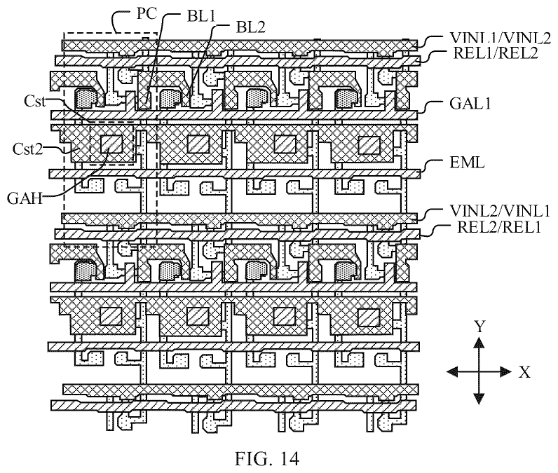

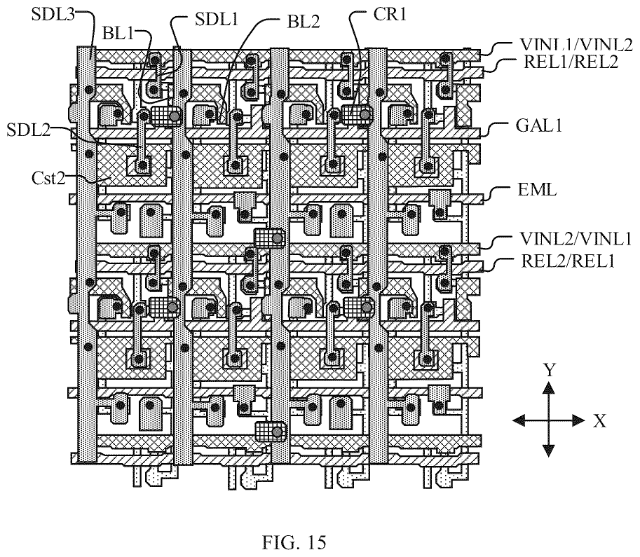

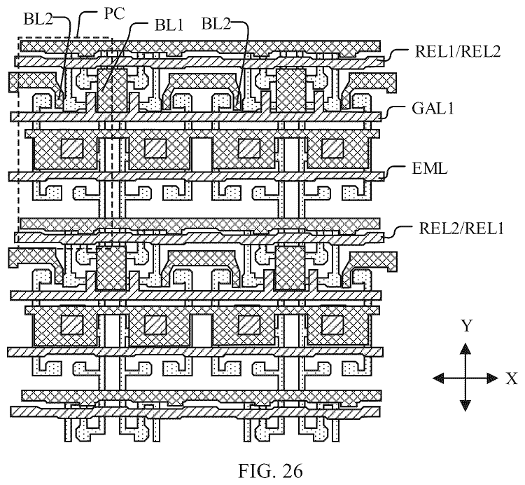

As shown in FIG. 8, FIG. 14, FIG. 20 and FIG. 26, the second gate layer GAT2 may include the second electrode plate Cst2 of the storage capacitor Cst, the first reset signal line VIL1 and the second reset signal line VIL2. The first reset signal line VIL1 and the second reset signal line VIL2 may extend along the row direction X and may be distributed along the column direction Y. The second electrode plate Cst2 is located between the first reset signal line VIL1 and the second reset signal line VIL2. The second electrode plate Cst2 overlaps with the first electrode plate Cst1 and has an opening. The orthographic projection of the first electrode plate Cst1 on the substrate SU may cover the orthographic projection of the opening on the substrate SU. In addition, the second gate layer GAT2 may further include at least one shielding block BL1. At least a partial area of the shielding block BL1 overlaps with the semiconductor layer SEL between the two channels of the compensation transistor T2, thereby shielding the compensation transistor T2 and preventing change of electrical characteristics of the compensation transistor T2 caused by light. In addition, the shielding block BL1 may also be connected to the power line VDL. On the one hand, it can play a role of signal shielding and prevent the compensation transistor T2 from being interfered by other signal(s). On the other hand, it can reduce the impedance of the power line VDL.

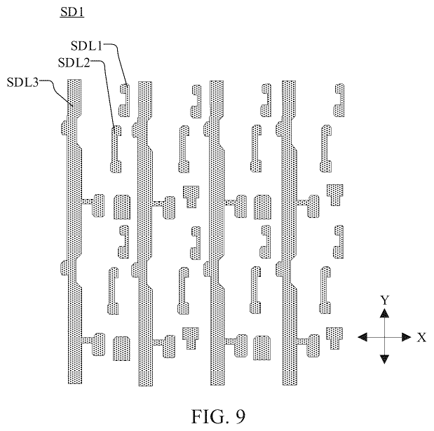

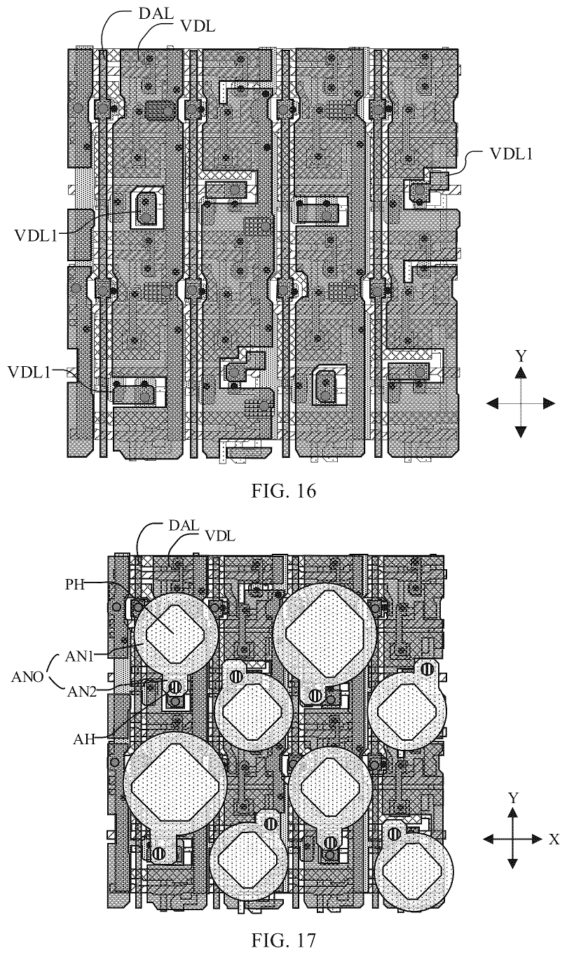

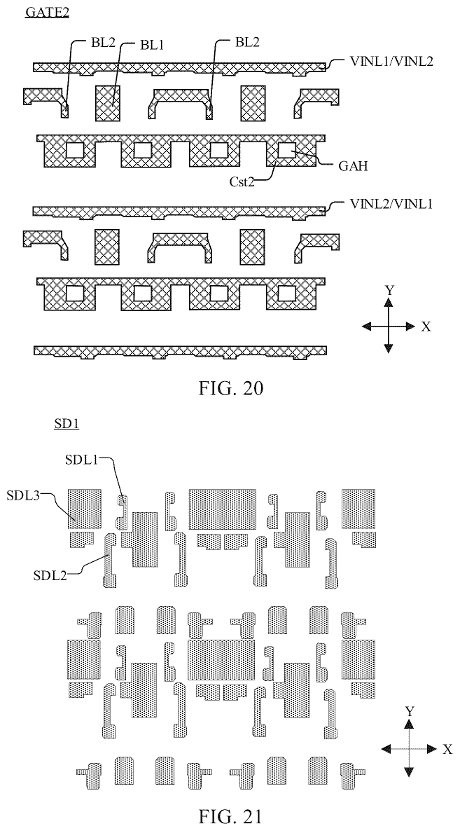

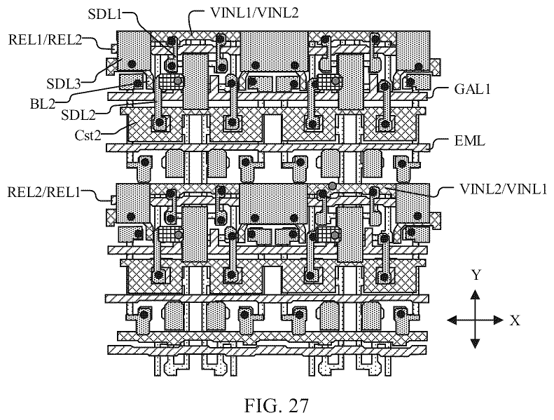

As shown in FIG. 9, FIG. 15, FIG. 21 and FIG. 27, the source-drain layer SD1 may include a plurality of connection portions. The connection portions may include a first connection portion SDL1 and a second connection portion SDL2. The first connection portion SDL1 may be connected with first reset transistor T1 and the first reset signal line VIL1 through via hole(s). The second connection portion SDL2 may be connected with the compensation transistor T2 and the first electrode plate Cst1 through via hole(s), and the via hole(s) connecting the compensation transistor T2 and the first electrode plate Cst1 passes (pass) through the opening of the second electrode plate Cst2 to connect the second electrode of the compensation transistor T2 and the gate of the driving transistor T3. Meanwhile, for a pixel circuit and its connected data line DAL, the second connection portion SDL2 may extend along the column direction Y, and the second connection portion SDL2 and the gate of the driving transistor T3 are located on the same side of the data line DAL.

In order to prevent the data signal on the data line DAL from interfering with the gate of the driving transistor T3 through the second connection portion SDL2, the second gate layer GAT2 may further include a screening block BL2, which is at least partially located between the data line DAL and the second connection portion SDL2. That is, the orthographic projection of the screening block BL2 on the substrate SU is at least partially located between orthographic projections of the data line DAL and the second connection portion SDL2 on the substrate SU. At the same time, the screening block BL2 may be connected to the power line VDL, so that the data signal of the data line DAL may be shielded by inputting a constant first power signal to the screening block BL2 to prevent it from interfering with the signal of the gate of the driving transistor T3.

The shielding block BL1 and the shielding block BL2 for two adjacent columns of pixel circuits PC may be of an integrated structure; alternatively, they may be independent of each other and distributed at intervals.

The second planarization layer PLN1 may be arranged on a side of the source-drain layer SD1 away from the substrate SU.

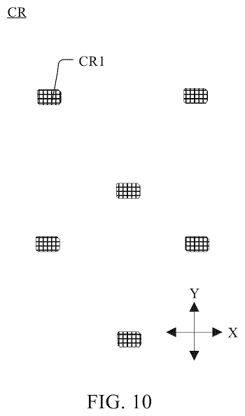

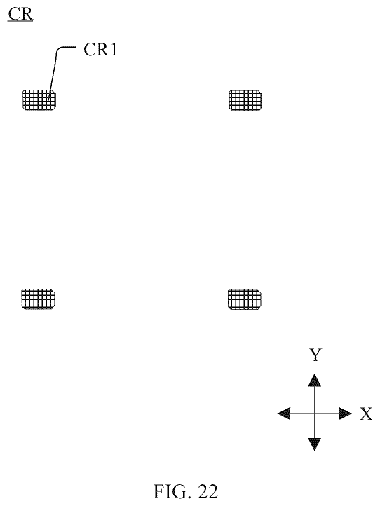

In addition, as shown in FIG. 10, FIG. 15, FIG. 22 and FIG. 27, the circuit layer CL may further include a conductive layer CR and an insulating layer EBB. The conductive layer CR may be arranged on a surface of the passivation layer PVX away from the substrate SU. The insulating layer EEB may cover the conductive layer CR. The second planarization layer PLN1 may cover the insulating layer EEB. The material of the insulating layer EEB may be inorganic material such as silicon nitride, of course, organic insulating material(s) may also be used. The conductive lines connecting the main display area MA and the auxiliary display area FA are located in the conductive layer CR. At the same time, the conductive layer CR may further include a plurality of overlapping portions CR1 located in the display area AA. The overlapping portions CRI are spaced apart from the conductive lines, and a pixel circuit PC may be connected to a power line VDL through an overlapping portion CR1, and thus interconnection may be realized through the overlapping part CR1. The material of the conductive layer CR may be transparent conductive material such as indium tin oxide, so as to reduce the influence of the conductive line on the light transmittance of the auxiliary display area FA.

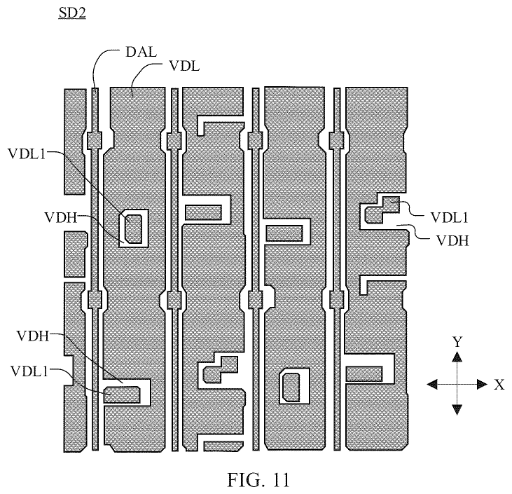

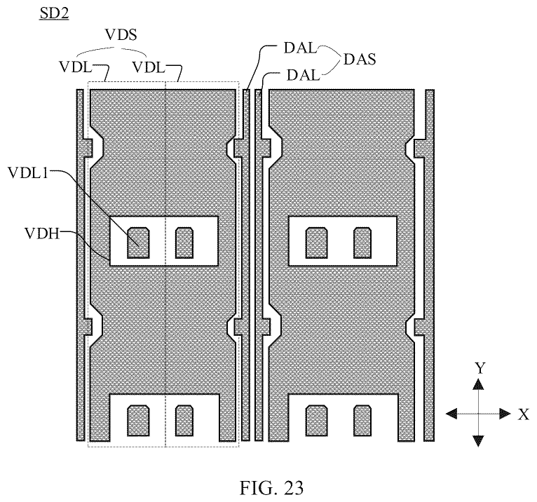

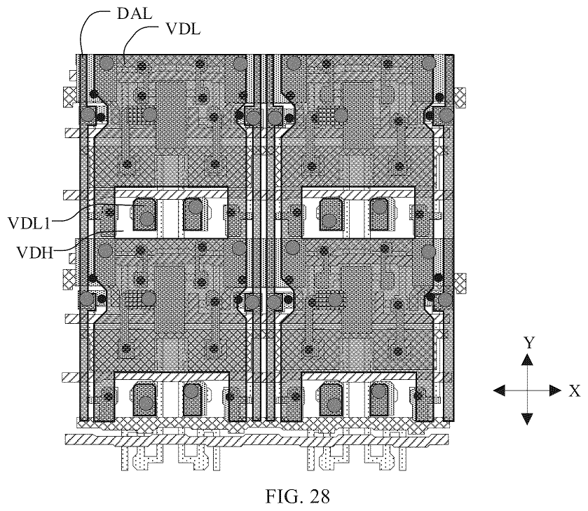

As shown in FIG. 11, FIG. 16, FIG. 23 and FIG. 28, the wiring layer SD2 may be arranged on a surface of the first planarization layer PLN2 away from the substrate SU. The inventors of the present disclosure found that the wiring layer SD2 is not a continuous whole layer structure, and its pattern may affect the flatness of the surface of the first planarization layer PLN2 away from the substrate SU, which in turn may directly affect the flatness of the first electrode ANO of the light-emitting device LD. If the flatness of the first electrode ANO is low, this may affect the optical path of the light reflected by the first electrode ANO, and after light exits from the anti-reflection layer COE, display defects such as color breakup and color shift are prone to occur. In order to solve this problem, the inventors of the present disclosure propose that by making the width of the power line VDL larger than that of the data line DAL and making the power line VDL overlap with at least part of the light-emitting devices LD, the power line VDL can at least level the inner area of the first electrode ANO in the range of the opening PH, to improve the flatness of the first electrode ANO within the range of the opening PH, thereby improving display abnormalities such as color breakup and color shift.

The width of the power line VDL is greater than that of the data line DAL, thereby increasing the area of the power line VDL, which is beneficial to leveling the first electrode ANO. The following is an exemplary description of the scheme of leveling the first electrode ANO by the power line VDL.

As shown in FIG. 3, FIG. 12 and FIG. 17, in a first implementation of the present disclosure, data lines DAL and power lines VDL are alternately distributed along the row direction X, and there is only one power line VDL between two adjacent data lines DAL. In the implementation, two pixel circuits PC which are adjacent in the row direction X may be obtained by shifting a pixel circuits PC along the row direction X.

A column of light-emitting devices LD may be arranged between two adjacent data lines DAL, that is, orthographic projections of only one column of light-emitting devices LD (using the opening PH) on the substrate SU are between orthographic projections of two adjacent data lines DAL on the substrate SU. It should be noted that, for a column of light-emitting devices LD, as long as more than 80% of their area is between the two data lines DAL, it may be considered that the column of light-emitting devices LD are between the two data lines DAL, not necessarily completely between the two data lines DAL. The column of light-emitting devices LD may overlap with the data lines DAL to some extent.

A power line VDL overlaps with a column of light-emitting devices LD. Among the light-emitting devices LD and the power line VDL which overlap with each other, the boundary of at least part of the light-emitting devices LD is located within the boundary of the overlapping power line VDL. That is, the orthographic projection of the opening PH of the at least part of the light-emitting devices LD on the substrate SU is located within the boundary of the power line VDL, so that at least the power line VDL may be used to level the first electrode ANO within the range of the opening PH. Of course, it is also possible that the boundary of at least part of the first electrodes ANO may be within the boundary of the power line VDL to further improve the flatness of the first electrodes ANO.

Further, light-emitting devices LD of a device column may overlap with a power line VDL. For example, the boundary of at least one of the second light-emitting device LDr and the third light-emitting device LDg is located within the boundary of the power line VDL which overlaps with the at least one of the second light-emitting device LDr and the third light-emitting device LDg. For example, the boundaries of the second light-emitting device LDr and the third light-emitting device LDg are all located within the boundary of the power line VDL which overlaps with the second light-emitting device LDr and the third light-emitting device LDg, and the range of the first light-emitting device LDb is relatively large, and it may exceed the boundary of the power line VDL to overlap with the data line DAL, but the exceeding area is no more than 20% of the first light-emitting device LDb.

In order to facilitate the connection between the light-emitting devices LD and the pixel circuits PC, a power line VDL may be provided with a plurality of through-holes VDH distributed along the column direction Y. The through-holes VDH are provided with interconnection portions VDL1 in the same layer as the power line VDL and spaced apart from the power line VDL. One of the interconnection portions VDL1 may be connected to an overlapping portion CR1, and connected to a pixel circuit PC through the overlapping portion CR1, so as to connect one of the first electrodes ANO to one of the pixel circuits PC.

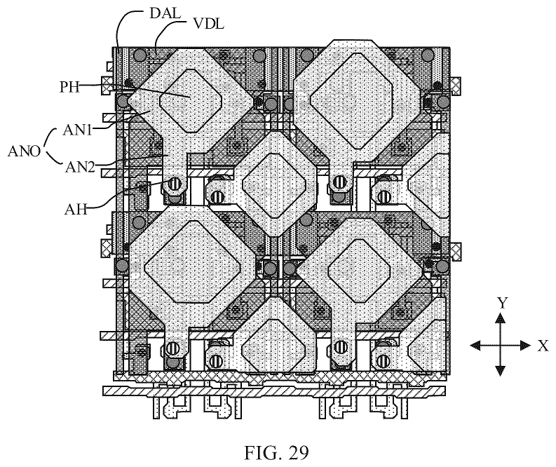

As shown in FIG. 4, FIG. 24 and FIG. 29, in a second implementation of the present disclosure, data lines DAL may be divided into a plurality of data line DAL groups, and one data line group DAS includes two data lines DAL. Power lines VDL may also be divided into a plurality of power line groups VDS, and one power line group VDS includes two power lines VDL. Meanwhile, the two power lines VDL of the same power line group VDS may be formed as an integrated structure, and the range of one power line group VDS is equal to the sum of the ranges of the two power lines VDL. At the same time, the data line groups DAS and the power line groups VDS may be alternately distributed along the row direction X, and one data line group DAS is provided between two adjacent power line groups VDS. In order to match the integrated structure of a power line group VDS, two columns of pixel circuits PC connected to the two power lines VDL of the power line group VDS may be arranged symmetrically with respect to a central axis of the two power lines VDL. The symmetrical arrangement means that patterns of film layers of the pixel circuits PC are distributed in mirror images with respect to the central axis.

Since a power line group VDS has two power lines VDL which are formed as an integrated structure, the area is increased, and the boundaries of at least part of the light-emitting devices LD may be located within the boundary of the power line VDL group, so that the increase of the power line VDL may be used to flatten the first electrode ANO of the light-emitting device LD, thereby alleviating display abnormalities such as color shift and color breakup. Meanwhile, due to the distribution of the light-emitting devices LD, a part of the light-emitting devices LD may overlap with the data line DAL groups.

Further, among the device columns, light-emitting devices LD of a part of the device columns overlap with a power line VDL group, and light-emitting devices LD of a part of the device columns overlap with a data line group DAS. For example, at most one of a second light-emitting device LDr and a third light-emitting device LDg overlaps with a data line DAL group. Further, the boundaries of the light-emitting devices LD in the first device column may be located within the boundary of a power line VDL group which overlaps with the light-emitting devices LD in the first device column, and light-emitting devices LD in the second device column may overlap with a data line DAL group.

Among two columns of pixel circuits PC connected to the same power line group VDS, shielding blocks BL1 of two adjacent columns of pixel circuits PC are formed as integrated, and the screening blocks BL2 of two adjacent columns of pixel circuits PC may be formed as integrated; alternatively, they may be mutually independent and spaced structures.

In addition, in order to facilitate the connection between the light-emitting devices LD and the pixel circuits PC, a plurality of through-holes VDH distributed along the column direction Y may be provided in each power line VDL group, and each through-hole VDH may be provided with an interconnection portion VDL1 which is arranged in the same layer as the power line VDL and is spaced apart from the power line VDL. One of the interconnection portions VDL1 may be connected with one of the pixel circuits PC. The third light-emitting devices LDg in the second device column overlap with a part of the through-holes VDH, in addition to overlapping with a data line group DAS.

The inventors of the present disclosure have also found that providing holes in the first planarization layer PLN2 may affect the flatness of the region around the holes. Based on this, if the distance between the opening PH and the contact hole AH connecting the first electrode ANO and the overlapping portion CRI is too close, that is, if the offset distance defined above is too small, it will affect the flatness of the area of the first electrode ANO which is located in the opening PH. Therefore, based on the first and second implementations above, the inventors have conducted tests and analysis to define the offset distance

For example, as shown in FIG. 3, FIG. 12 and FIG. 17, for the above first implementation, the offset distance Sb of the first light-emitting device LDb is 2.9 μm to 3 μm, for example 2.93 μm. The offset distance Sb of the second light-emitting device is 6.5 μm to 6.6 μm, for example, 6.56 μm. The offset distance Sg of the third light-emitting device LDg is 5.2 μm to 5.3 μm, for example, 5.24 μm. In addition, in the same light emitting unit, the distance Sbg between the first light-emitting device LDb and the third light-emitting device LDg is smaller than the distance Srg between the second light-emitting device LDr and the third light-emitting device LDg.

For example, as shown in FIG. 4, FIG. 24 and FIG. 29, for the second implementation above, the offset distance Sb of the first light-emitting device LDb is 9 μm to 11 μm, for example, 10 μm. The offset distance Sr of the second light-emitting device LDr is 15 μm to 17 μm, for example 16 μm. The offset distance Sg of the third light-emitting device LDg is 6 μm to 8 μm, for example 7 μm.

The present disclosure further provides a display device, which may include the display panel in any of the above implementations, and its specific structure and beneficial effects may refer to the above implementations of the display panel, which will not be repeated here. The display device of the present disclosure may be a smart watch or a wristband, or the display device may be used in an electronic device with a display function such as mobile phone or tablet computer, which will not be listed here.

Other embodiments of the present disclosure will be readily apparent to those skilled in the art from consideration of the specification and practice of the invention disclosed herein. The present disclosure is intended to cover any modification, use or adaptation of the present disclosure, and these modifications, uses or adaptations follow the general principles of the present disclosure and include common knowledge or conventional technical means in the technical field not disclosed in the present disclosure. The specification and examples are to be considered exemplary only, with the true scope and spirit of the disclosure indicated by the appended claims.

1. A display panel, comprising:
a driving backplane comprising a substrate and a circuit layer, a wiring layer and a first planarization layer which are stacked in sequence along a direction away from the substrate; wherein:
the circuit layer comprises a plurality of pixel circuits distributed in an array;
the wiring layer comprises data lines and power lines distributed along a row direction, and one of the data lines and one of the power lines are connected to a column of the pixel circuits;
the power lines have a width larger than that of the data lines;
the power lines are provided with a plurality of through-holes distributed in a column direction, the through-holes are provided with interconnection portions which are arranged in a same layer as the power lines and are spaced from the power lines, and one of the interconnection portions is connected to one of the pixel circuits;
a plurality of light-emitting devices distributed in an array on a side of the first planarization layer away from the substrate and connected to the pixel circuits, wherein each of the light-emitting devices comprises a first electrode, a light-emitting layer and a second electrode which are stacked in sequence along the direction away from the substrate, the light-emitting devices comprises at least two kinds of light-emitting devices which emit light of different colors, and at least part of the light-emitting devices overlap with an area of the power lines where no through-hole is provided; and
an anti-reflection layer arranged on a side of the light-emitting devices away from the substrate, and comprising a plurality of filter portions distributed in an array, wherein one of the filter portions overlaps with one of the light-emitting devices, and a color of one of the filter portions is the same as a color of light emitted by a light-emitting device which overlaps with the one of the filter portions.

2. The display panel according to claim 1, wherein:
the data lines and the power lines are alternately distributed along the row direction;
one of the power lines overlaps with a column of the light-emitting devices, and a column of the light-emitting devices is provided between two adjacent data lines; and
among light-emitting devices and power lines which overlap with each other, a boundary of at least part of the light-emitting devices is located within a boundary of power lines which overlap with the at least part of the light-emitting devices.

3. The display panel according to claim 2, wherein the light-emitting devices are arranged in a plurality of device columns along the row direction, and one of the device columns of the light-emitting devices overlap with one of the power lines.

4. The display panel according to claim 3, wherein:
the light-emitting devices comprise a first light-emitting device of a first color, a second light-emitting device of a second color, and a third light-emitting device of a third color;
a range of the first light-emitting device is larger than that of the second light-emitting device and the third light-emitting device, and a boundary of at least one of the second light-emitting device and the third light-emitting device is located within a boundary of a power line which overlaps with the at least one of the second light-emitting device and the third light-emitting device.

5. The display panel according to claim 4, wherein the device columns comprise a first device column and a second device column alternately distributed along the row direction, the first device column comprises the first light-emitting device and the second light-emitting device which are alternately distributed along the column direction, and the second device column comprises the third light-emitting device.

6. The display panel according to claim 4, wherein the first electrode comprises an electrode body and an electrode connection portion extending outward from the electrode body, and one electrode connection portion is connected to one of the pixel circuits through a contact hole which passes through the first planarization layer;
wherein the display panel further comprises:
a pixel definition layer arranged on a side of the first planarization layer away from the substrate and provided with a plurality of openings for defining ranges of the light-emitting devices, one of the openings exposes one electrode body, and a distance between one of the openings and a contact hole connected to an electrode connection portion connected to an electrode body exposed by the one of the openings is an offset distance of a light-emitting device defined by the one of the openings;
wherein the offset distance of the first light-emitting device is 2.9 μm to 3 μm, the offset distance of the second light-emitting device is 6.5 μm to 6.6 μm, and the offset distance of the third light-emitting device is 5.2 μm to 5.3 μm.

7. The display panel according to claim 1, wherein:
the data lines are divided into a plurality of data line groups, and one of the data line groups comprises two of the data lines;
the power lines are divided into a plurality of power lines groups, and one of the power line groups comprises two power lines, and the two power lines are formed as an integrated structure;
the data line groups and the power line groups are alternately distributed along the row direction;
two columns of pixel circuits connected to two power lines in one of the power line groups are arranged symmetrically with respect to a central axis of the two power lines;
a boundary of at least part of the light-emitting devices is located within a boundary of the power line groups, and at most part of the light-emitting devices overlap with the data line groups.

8. The display panel according to claim 7, wherein the light-emitting devices are arranged in a plurality of device columns along the row direction, and light-emitting devices of a part of the device columns overlap with one of the power line groups, and light-emitting devices of a part of the device columns overlap with the data line groups.

9. The display panel according to claim 8, wherein the light-emitting devices comprise a first light-emitting device of a first color, a second light-emitting device of a second color, and a third light-emitting device of a third color;
a range of the first light-emitting device is larger than that of the second light-emitting device and the third light-emitting device, a boundary of the first light-emitting device is located within a boundary of a power line group which overlaps with the first light-emitting device, and at most one of the second light-emitting device and the third light-emitting device overlaps with a data line group.

10. The display panel according to claim 9, wherein:
the device columns comprise a first device column and a second device column alternately distributed along the row direction;
the first device column comprises the first light-emitting device and the second light-emitting device which are alternately distributed along the column direction, and the second device column comprises the third light-emitting device; and
a boundary of light-emitting devices of the first device column are located within a boundary of a power line group which overlaps with the light-emitting devices of the first device column, and light-emitting devices of the second device column overlap with a data line group.

11. The display panel according to claim 10, wherein the first electrode comprises an electrode body and an electrode connection portion extending outward from the electrode body, and one electrode connection portions is connected to one of the pixel circuits through a contact hole which passes through the first planarization layer;
wherein the display panel further comprises:
a pixel definition layer arranged on a side of the first planarization layer away from the substrate and provided with a plurality of openings for defining ranges of the light-emitting devices, one of the openings exposes one electrode body, and a boundary of the one of the openings is located within a boundary of an electrode body exposed by the one of the openings;
a distance between one of the openings and a contact hole connected to an electrode connection portion connected to an electrode body exposed by the one of the openings is an offset distance of a light-emitting device defined by the one of the openings;
wherein the offset distance of the first light-emitting device is 9 μm to 11 μm, the offset distance of the second light-emitting device is 15 μm to 17 μm, and the offset distance of the third light-emitting device is 6 μm to 8 μm.

12. The display panel according to claim 1, wherein:
each of the pixel circuits comprises a plurality of transistors;
the circuit layer comprises a semiconductor layer, a first gate insulating layer, a first gate layer, a second gate insulating layer, a second gate layer, a dielectric layer, a source-drain layer, a passivation layer, and a second planarization layer which are distributed along the direction away from the substrate;
the wiring layer is arranged on a side of the second planarization layer away from the substrate; and
channels of the transistors are located in the semiconductor layer.

13. The display panel according to claim 12, wherein in a pixel circuit and a data line and a power line connected to the pixel circuit, the pixel circuit comprises a first reset transistor, a compensation transistor, a driving transistor, a writing transistor, a first light-emitting control transistor, a second light-emitting control transistor, a second reset transistor and a storage capacitor;
wherein:
a first electrode of the first reset transistor is used to receive a first reset signal, and a second electrode of the first reset transistor is connected to a gate of the driving transistor and a first electrode plate of the storage capacitor;
a first electrode of the compensation transistor is connected to a second electrode of the driving transistor, and a second electrode of the compensation transistor is connected to the gate of the driving transistor, and the compensation transistor has two channels connected in series;
a first electrode of the writing transistor is connected to one of the data lines, and a second electrode of the writing transistor is connected to a first electrode of the driving transistor;
a first electrode of the first light-emitting control transistor is connected to a second electrode plate of the storage capacitor and the power line, and a second electrode of the first light-emitting control transistor is connected to the first electrode of the driving transistor;
a first electrode of the second light-emitting control transistor is connected to the second electrode of the driving transistor, and a second electrode of the second light-emitting control transistor is connected to one first electrode through an interconnection portion;
a first electrode of the second reset transistor is used to receive a second reset signal, and a second electrode of the second reset transistor is connected to the second electrode of the second light-emitting control transistor;
the first gate layer comprises gates of the transistors and the first electrode plate of the storage capacitor, the second gate layer comprises the second electrode plate of the storage capacitor, a shielding block and a screening block, the source-drain layer comprises a connection portion connecting the second electrode of the compensation transistor and the gate of the driving transistor, and the connection portion and the gate of the driving transistor are located on the same side of the data line;
at least a partial area of the shielding block overlaps with a semiconductor layer between the two channels of the compensation transistor, the screening block is at least partially located between the data line and the connection portion, and the screening block is connected to the power line.

14. The display panel according to claim 6, wherein the display panel comprises a display area, and the display area comprises an auxiliary display area and a main display area outside the auxiliary display area, and the light-emitting devices are distributed in the main display area and the auxiliary display area;
wherein a pixel circuit connected to at least part of the light-emitting devices in the auxiliary display area is located in the main display area and connected to the light-emitting devices through a conductive line;
wherein the circuit layer further comprises a conductive layer and an insulating layer, the conductive layer is arranged on a side of the passivation layer away from the substrate, the insulating layer covers the conductive layer, the second planarization layer covers the insulating layer, and the conductive layer comprises the conductive line.

15. The display panel according to claim 14, wherein the conductive layer further includes a plurality of overlapping portions located in the display area, and one of the pixel circuits is connected to a power line through one of the overlapping portions.

16. A display device, comprising a display panel,
wherein the display panel comprises:
a driving backplane comprising a substrate and a circuit layer, a wiring layer and a first planarization layer which are stacked in sequence along a direction away from the substrate; wherein:
the circuit layer comprises a plurality of pixel circuits distributed in an array;
the wiring layer comprises data lines and power lines distributed along a row direction, and one of the data lines and one of the power lines are connected to a column of the pixel circuits;
the power lines have a width larger than that of the data lines;
the power lines are provided with a plurality of through-holes distributed in a column direction, the through-holes are provided with interconnection portions which are arranged in a same layer as the power lines and are spaced from the power lines, and one of the interconnection portions is connected to one of the pixel circuits;
a plurality of light-emitting devices distributed in an array on a side of the first planarization layer away from the substrate and connected to the pixel circuits, wherein each of the light-emitting devices comprises a first electrode, a light-emitting layer and a second electrode which are stacked in sequence along the direction away from the substrate, the light-emitting devices comprises at least two kinds of light-emitting devices which emit light of different colors, and at least part of the light-emitting devices overlap with an area of the power lines where no through-hole is provided; and
an anti-reflection layer arranged on a side of the light-emitting devices away from the substrate, and comprising a plurality of filter portions distributed in an array, wherein one of the filter portions overlaps with one of the light-emitting devices, and a color of one of the filter portions is the same as a color of light emitted by a light-emitting device which overlaps with the one of the filter portions.

17. The display panel according to claim 1, wherein the first electrode is made of a reflective material.

18. The display device according to claim 16, wherein:
the data lines and the power lines are alternately distributed along the row direction;
one of the power lines overlaps with a column of the light-emitting devices, and a column of the light-emitting devices is provided between two adjacent data lines; and
among light-emitting devices and power lines which overlap with each other, a boundary of at least part of the light-emitting devices is located within a boundary of power lines which overlap with the at least part of the light-emitting devices.

19. The display device according to claim 18, wherein the light-emitting devices are arranged in a plurality of device columns along the row direction, and one of the device columns of the light-emitting devices overlap with one of the power lines.

20. The display device according to claim 19, wherein:
the light-emitting devices comprise a first light-emitting device of a first color, a second light-emitting device of a second color, and a third light-emitting device of a third color;
a range of the first light-emitting device is larger than that of the second light-emitting device and the third light-emitting device, and a boundary of at least one of the second light-emitting device and the third light-emitting device is located within a boundary of a power line which overlaps with the at least one of the second light-emitting device and the third light-emitting device.
